(19) United States
(12) Patent Application Publication
(10) Pub. No.: US 2010/0062559 A1
(43) Pub. Date: Mar. 11, 2010

(54) Methods of manufacturing image sensors having shielding members

(75) Inventors: Jin-Hyeong Park, Seoul (KR); Taek-Soo Kim, Suwon-si (KR); Chan Park, Yongin-si (KR); Jong-Cheol Shin, Hwaseong-si (KR); Young-Hyun Lee, Hwaseong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/585,349

(22) Filed: Sep. 11, 2009

(30) Foreign Application Priority Data
Sep. 11, 2008 (KR) 10-2008-0089646

(51) Int. Cl. H01L 31/18

(52) U.S. Cl. 438/65; 257/E31.121; 438/70; 257/E31.11; 257/E31.127

(57) ABSTRACT

An epitaxial layer may be formed on a substrate having a first region and a second region. A photo diode may be formed on a first portion of the epitaxial layer in the first region of the substrate. At least one transfer transistor may be formed on the epitaxial layer adjacent to the photo diode. A plurality of transistors may be formed on a second portion of the epitaxial layer in the second region. An insulation layer may be formed to cover the photo diode, the at least one transfer transistor and the plurality of transistors. A plurality of connections may be formed through the insulation layer to be electrically connected with the at least one transfer transistor and the plurality of transistors in the second region. A shielding member may be formed to expose the photo diode. The epitaxial layer and/or the substrate may be treated with a hydrogen plasma before forming the shielding member to remove dangling bonds of silicon-oxygen and/or silicon-silicon.

### CROSS-REFERENCE TO RELATED APPLICATION

This application claims priority under 35 U.S.C. §119 to Korean Patent Application No. 10-2008-0089646, filed on Sep. 11, 2008, in the Korean Intellectual Property Office (KIPO), the entire contents of which are incorporated by reference herein.

### BACKGROUND

1. Technical Field

Example embodiments relate to image sensors and methods of manufacturing image sensors. More particularly, example embodiments relate to complementary metal oxide semiconductor (CMOS) image sensors including shielding members and methods of manufacturing the CMOS image sensors.

2. Description of the Related Art

Image sensors usually convert optical images into electrical signals. The image sensors are widely employed in various electronic apparatuses, e.g., mobile phones, personal communication systems, camcorders, electronic games, and/or digital cameras. When the conventional image sensor has an increased integration degree to enhance the resolution thereof, the conventional image sensor may have lowered sensitivity because photoelectric transformation elements, e.g., photo diodes, have reduced sizes in a unit pixel. The conventional image sensor may have defects, e.g., images caused by reduced current storage capacity and lowered transmission efficiency due to noises and dark current.

The dark current in the image sensor is generated by accumulated charges in the image sensor without incident lights, which is mainly caused by the surface defects of a substrate or dangling bonds of silicon-oxygen (Si—O) and/or silicon-silicon (Si—Si) in the substrate on which the image sensor is provided. When the dangling bonds exist in the substrate, the dark current may be more easily generated in the image sensor, thereby deteriorating the quality of the image produced from the image sensor. When the dangling bonds of silicon-oxygen and/or silicon-silicon exist on a portion of the substrate on which a transfer transistor of the unit pixel, thermal electrons may be diffused into a photo diode of the image sensor. The diffused electrons may generate the electrical signal in the image sensor even though the lights are not input into the image sensor, which cause the noises, the dark current and/or the dark level difference between an active pixel region and an optical black pixel region of the substrate. Therefore, the image sensor may have an undesirable quality of images and deteriorated electrical and optical characteristics.

FIG. 1 is a schematic plan view illustrating the conventional CMOS image sensor. As shown in FIG. 1, the conventional CMOS image sensor 10 includes an active pixel array region 20 and a CMOS control circuit 30. The active pixel array region 20 includes a plurality of unit pixels 22 disposed in a matrix structure.

The CMOS control circuit 30 positioned near the active pixel array region 20 includes a plurality of CMOS transistors. The CMOS control circuit 30 provides predetermined or given signals to the unit pixels 22 in the active pixel array region 20. The CMOS control circuit 30 also controls output signals of the unit pixels 22 in the active pixel array region 20 by the output line.

FIG. 2 is an equivalent circuit diagram illustrating a unit pixel of the conventional CMOS image sensor. Referring to FIG. 2, the unit pixel 22 includes a photo diode (PD) generating photo charges after receiving lights from outside. The photo charges are transferred from the photo diode (PD) to a floating diffusion region (FD) by a transfer transistor (Tx). A reset transistor (Rx) periodically resets the charges stored in the floating diffusion region (FD), and a drive transistor (Dx) buffers signals generated from the stored charges in the floating diffusion region (FD). The drive transistor (Dx) also serves as a source follower buffer amplifier. A selection transistor (Sx) serves as a switch for selecting a required unit pixel.

FIG. 3 is a cross sectional view illustrating the conventional CMOS image sensor. Referring to FIG. 3, the conventional CMOS image sensor includes a semiconductor substrate 50, a semiconductor layer 55, isolation layers 60, a channel region 65, a photo diode 68, a gate insulation layer 70, a plurality of gate structures 72, a first insulation layer 75, a second insulation layer 78, a plurality of wirings 80, a third insulation layer 85, a shielding layer 86, a protection layer 87, a metal pad 88, a transparent layer 90, and a micro lens 91.

In the conventional CMOS transistor, the shielding layer 86 covers an optical black pixel region of the substrate 50 and exposes an active pixel region of the substrate 50, so that dangling bonds of silicon-oxygen (Si—O) or silicon-silicon (Si—Si) may not be removed in the substrate 50 and the semiconductor layer 55. When a plasma treatment is executed on the substrate 50 having the photo diode 68, the dangling bonds may be cured in the active pixel region while the dangling bonds may not be removed in the optical black pixel region because of the shielding layer covering the Optical black pixel region. Accordingly, the conventional CMOS image sensor may not provide an image of an object with a higher quality because dark current and dark level difference may occur due to the remaining dangling bonds in the optical black pixel region.

### SUMMARY

Example embodiments provide image sensors including shielding members after performing hydrogen plasma treatment to ensure a high quality image of an object with improved electrical and optical characteristics.

Example embodiments provide methods of manufacturing image sensors including shielding members after performing hydrogen plasma treatment to achieve a high quality image of an object with improved electrical and optical characteristics.

According to example embodiments, there is provided an image sensor including a substrate, an epitaxial layer on the substrate, a photo diode, at least one transfer transistor, a plurality of transistors, an insulation layer, a plurality of connections configured to electrically contact the at least one transfer transistor and the plurality of transistors, a transparent layer, a protection layer and a shielding member. The substrate may include a first region and a second region. The photo diode may be on a first portion of the epitaxial layer in the first region of the substrate. The at least one transfer transistor may be positioned on the first portion of the epitaxial layer adjacent to the photo diode. The plurality of transistors may be on a second portion of the epitaxial layer in the second region of the substrate. The insulation layer may cover the photo diode, the at least one transfer transistor and the plurality of transistors on the epitaxial layer. The plurality of connections may be configured to contact the at least one transfer transistor and the plurality of transistors through the insulation layer in the second region of the substrate. The transparent layer may be positioned on the photo diode through the insulation layer in the first region. The protection layer may cover the plurality of connections. The shielding member may be located on the protection layer, the shielding member exposing the transparent layer.

In example embodiments, a metal pad contacting the plurality of connections may be additionally provided through the protection layer and the insulation layer. The shielding member and the metal pad may be simultaneously formed. The shielding member and the metal pad may include a metal and/or a metal compound. In example embodiments, the first region may be an active pixel region and the second region may be an optical black pixel region.

In example embodiments, a first well and a second well may be additionally provided in the first region. The epitaxial layer may have a first conductivity, and the first well may have a second conductivity different from the first conductivity. Further, the second well may have a third conductivity identical to the first conductivity. In example embodiments, a micro lens may be on the transparent layer. The transparent layer may include resin.

According to example embodiments, there is provided an image sensor including a substrate having a first region and a second region, a plurality of insulation layers on the substrate, a plurality of connections through the insulation layers, a plurality of transistors electrically connected to the plurality of connections, an epitaxial layer covering the plurality of transistors, a photo diode on a portion of the epitaxial layer adjacent to the plurality of transistors, a protection layer on the epitaxial layer and a shielding member on the protection layer. The protection layer exposes a portion of the epitaxial layer under which the photo diode is located.

In example embodiments, a color filter layer may be on the portion of the epitaxial layer exposed by the protection layer, and a micro lens may be provided on the color filter layer. The shielding member may include a metal and/or a metal compound.

According to example embodiments, there is provided a method of manufacturing an image sensor. In the method of manufacturing the image sensor, an epitaxial layer may be formed on a substrate having a first region and a second region. A photo diode may be formed on a first portion of the epitaxial layer in the first region of the substrate. At least one transfer transistor may be formed on the epitaxial layer adjacent to the photo diode. A plurality of transistors may be formed on a second portion of the epitaxial layer in the second region of the substrate. An insulation layer may be formed on the epitaxial layer to cover the photo diode, the at least one transfer transistor and the plurality of transistors. A plurality of connections may be formed through the insulation layer. The plurality of connections may be electrically connected with the at least one transfer transistor and the plurality of transistors in the second region of the substrate. A shielding member exposing the photo diode may be formed.

In example embodiments, a first well and a second well may be formed on the second portion of the epitaxial layer before forming the photo diode. In example embodiments, the epitaxial layer and the substrate may be treated with a hydrogen plasma before forming the shielding member to remove dangling bonds of silicon-oxygen and/or silicon-silicon in the epitaxial layer and the substrate. The epitaxial layer and the substrate may be treated using a hydrogen (H₂) gas and an argon (Ar) gas at a temperature of about 300° C. to about 400° C.

In example embodiments, a transparent layer may be formed on the photo diode through the insulation layer in the first region of the substrate, and a protection layer may be formed on the insulation layer to cover the plurality of connections. Further, a color filter layer may be formed on the transparent layer, and a micro lens may be formed on the color filter layer.

In example embodiments, a metal pad may be formed through the insulation layer to electrically connect with the plurality of connections. The shielding member and the metal pad may be simultaneously formed. In example embodiments, an additional substrate may be formed on the insulation layer before forming the shielding layer, and the substrate may be removed from the epitaxial layer. A protection layer may be formed between the epitaxial layer and the shielding member. The epitaxial layer may be treated with hydrogen plasma before forming the shielding member.

According to example embodiments, dangling bonds of silicon-oxygen and/or silicon-silicon may be effectively removed from the substrate or the epitaxial layer on which the photo diode of the image sensor is positioned. Thus, the image sensor may improve the quality of the image with enhanced electrical and optical characteristics while preventing or reducing the dark level difference of the image and/or the dark current in the photo diode. When the image sensor is coupled to a memory device, e.g., a flash memory device, the image of the object may be more easily stored or displayed with higher quality. Further, the image sensor may be employed in various electronic systems, for example, mobile phones, digital cameras, video games, video conference systems and/or telemedicine systems.

### BRIEF DESCRIPTION OF THE DRAWINGS

Example embodiments can be understood in more detail from the following description taken in conjunction with the accompanying drawings, in which:

FIG. 1 is a schematic plan view illustrating the conventional CMOS image sensor;

FIG. 2 is an equivalent circuit diagram illustrating a unit pixel of the conventional CMOS image sensor;

FIG. 3 is a cross sectional view illustrating the conventional CMOS image sensor;

FIGS. 4 to 11 are cross sectional views illustrating methods of manufacturing image sensors having shielding members in accordance with example embodiments;

FIGS. 12 to 20 are cross sectional views illustrating other methods of manufacturing image sensors having shielding members in accordance with example embodiments;

FIG. 21 is a block diagram illustrating an electronic system including a CMOS image sensor in accordance with example embodiments;

FIG. 22 is a block diagram illustrating a CMOS image sensor including a shielding member in accordance with example embodiments; and

FIG. 23 is a block diagram illustrating another electronic system including a CMOS image sensor in accordance with example embodiments.

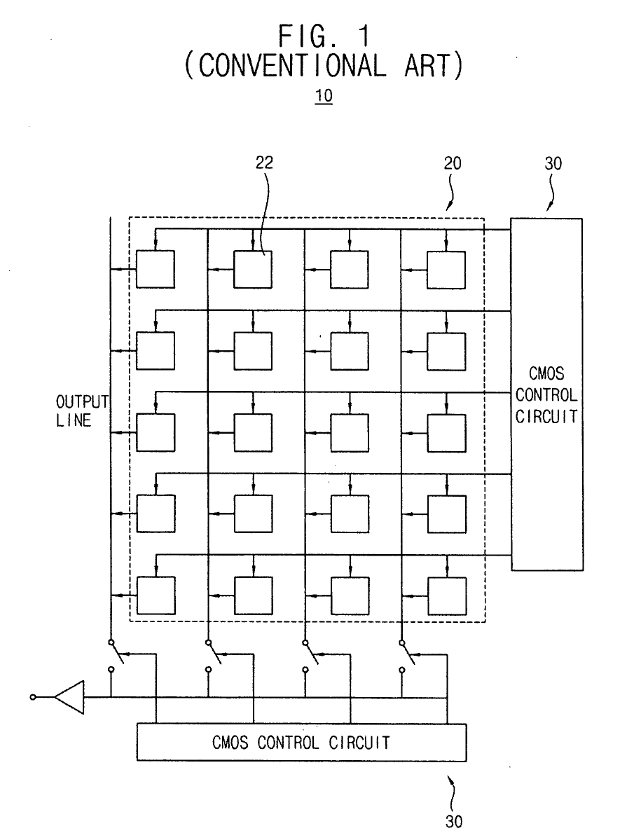

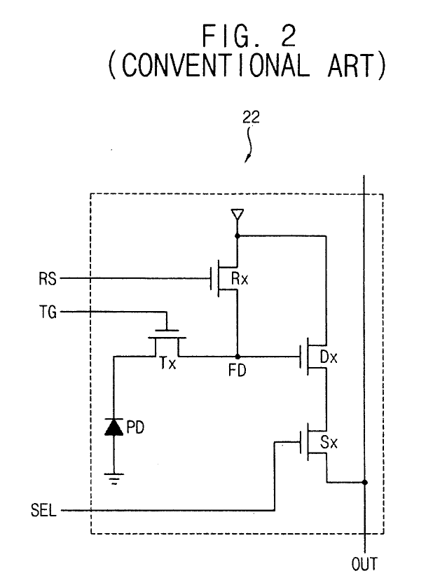

### DETAILED DESCRIPTION OF EXAMPLE EMBODIMENTS

Example embodiments are described more fully hereinafter with reference to the accompanying drawings. The inventive concept may, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like or similar reference numerals refer to like or similar elements throughout. As used herein, the term “and/or” includes any and all combinations of one or more of the associated listed items.

It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of illustratively idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

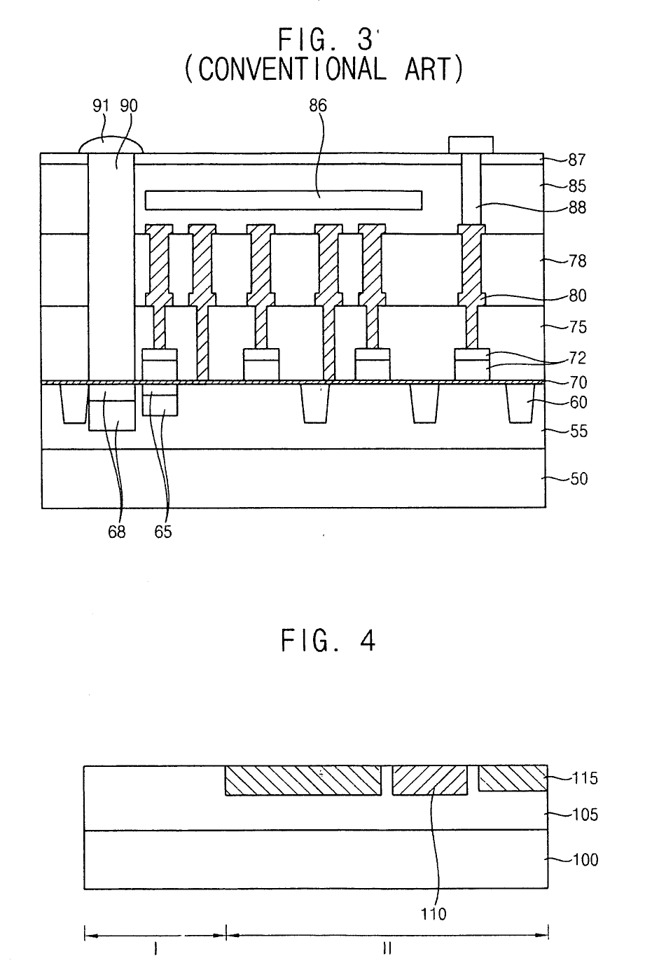

FIGS. 4 to 11 are cross sectional views illustrating methods of manufacturing image sensors having shielding members in accordance with example embodiments. Although the method illustrates a complementary metal oxide semiconductor (CMOS) image sensor in FIGS. 4 to 11, example embodiments may be properly employed in manufacturing other image sensors, e.g., contact image sensors and/or solid state image sensors.

Referring to FIG. 4, a substrate 100 having a first region I and a second region II is provided. The substrate 100 may include a semiconductor substrate, for example, a silicon (Si) substrate, a germanium (Ge) substrate and/or a silicon-germanium (Si—Ge) substrate. In example embodiments, the first region I may correspond to an active pixel region and the second region II may be an optical black pixel region. An active pixel sensor (APS) array and common devices may be provided on the substrate 100. Photo diodes may be positioned in the active pixel region through which a light passes whereas transfer transistors and logic devices, e.g., CMOS transistors, may be located in the optical black pixel region where the light does not penetrate.

According to example embodiments, the substrate 100 may include a semiconductor substrate that is doped with impurities. The substrate 100 may include P type impurities or N type impurities. For example, the substrate 100 may include boron (B), indium (in), gallium (Ga), aluminum (Al), arsenic (As), phosphorus (P) or antimony (Sb) doped into a predetermined or given portion of the substrate 100.

An epitaxial layer 105 may be formed on the substrate 100. The epitaxial layer 105 may be formed by an epitaxial growth process using the substrate 100 as a seed. In example embodiments, the epitaxial layer 105 may have a first conductivity. The first conductivity of the epitaxial layer 105 may be substantially the same as that of the substrate 100. The epitaxial layer 105 may have a thickness of about 5 μm to about 15 μm based on an upper face of the substrate 100. However, the thickness of the epitaxial layer 105 may vary in accordance with dimensions of elements provided on the epitaxial layer 105.

A first well 110 and a second well 115 may be formed in the epitaxial layer 105. Each of the first and the second wells 110 and 115 may be formed by an ion implantation process and a diffusion process. The first well 110 may have a second conductivity and the second well 115 may have a third conductivity. In example embodiments, the first well 110 may have the second conductivity different from the first conductivity of the epitaxial layer 105. However, the second well 115 may have the third conductivity substantially the same as the first conductivity of the epitaxial layer 105.

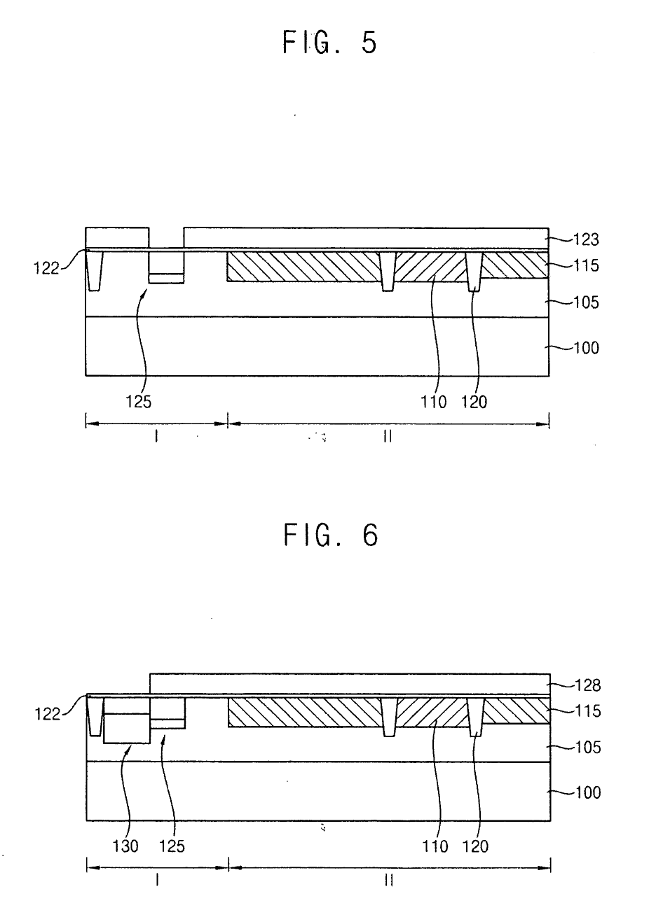

Referring to FIG. 5, an isolation layer 120 may be formed on a portion of the epitaxial layer 105 between the first well 110 and the second well 115. The first well 110 may be electrically separated from the second well 115 by the isolation layer 120. The isolation layer 120 may be formed by an isolation process, e.g., a shallow trench isolation (STI) process. Further, the isolation layer 120 may include oxide, for example, spin on glass (SOG), undpoed silicate glass (USG), followable oxide (FOX), phosphor silicate glass (PSG), boro-phosphor silicate glass (BPSG), tetraethylortho silicate (TEOS), tonensilazene (TOSZ) and/or high density plasma-chemical vapor deposition (HDP-CVD) oxide.

In example embodiments, the isolation layer 120 may have a depth substantially different from that of another isolation layer positioned between adjacent photo diodes (not illustrated). For example, the isolation layer 120 formed in the optical black pixel region may have a thickness substantially different from that of another isolation layer located in the active pixel region.

Generally, the photo diodes (not illustrated) may operate by absorbing red light, green light and blue light into the epitaxial layer 105 to improve the accumulation density of the photo diodes. Each of the photo diodes may have a depth above about 2.0 μm because the red light may have the largest wavelength of about 0.4 μm to about 5.0 μm. The isolation layer 120 may sufficiently isolate adjacent transfer transistors and/or adjacent logic devices when the isolation layer 120 has a thickness of about 2.0 μm. Thus, another isolation layer formed between adjacent photo diodes may have a thickness substantially larger than that of the isolation layer 120 provided between adjacent transfer transistors and/or adjacent logic devices.

After forming the isolation layer 120, a gate insulation layer 122 may be formed on the epitaxial layer 105 having the first and the second wells 110 and 115. The gate insulation layer 122 may cover the active pixel region and the optical black pixel region. In example embodiments, the gate insulation layer 122 may include oxide and/or metal oxide. For example, the gate insulation layer 122 may include silicon oxide (SiOx), hafnium oxide (HfOx), aluminum oxide (AlOx), zirconium oxide (ZrOx) and/or tantalum oxide (TaOx). These may be used alone or in a mixture thereof. Further, the gate insulation layer 122 may be formed by a CVD process, a thermal oxidation process, a plasma enhanced chemical vapor deposition (PECVD) process and/or an atomic layer deposition (ALD) process.

A first mask 123 may be formed on the gate insulation layer 122. The first mask 123 may be obtained by patterning a photoresist film formed on the gate insulation layer 122 through an exposure process and a developing process. The first mask 123 may expose a first portion of the epitaxial layer 105 where the transfer transistor is positioned.

First impurities and second impurities may be doped into the exposed first portion of the epitaxial layer 105 to form a gate channel 125 of the transfer transistor. The first mask 123 may serve as an implantation mask for forming the gate channel 125 in an ion implantation process. In example embodiments, the first impurities may have a fourth conductivity and the second impurities may have a fifth conductivity. The fourth conductivity of the first impurities may be substantially the same as the first conductivity of the epitaxial layer 105 whereas the fifth conductivity of the second impurities may be substantially different from the first conductivity of the epitaxial layer 105. Alternatively, the fourth conductivity of the first impurities may be substantially different from the first conductivity and the fifth conductivity of the second impurities may be substantially the same as the first conductivity. That is, the conductivities of the first and the second impurities may vary in accordance with a conductivity of the gate channel 125.

Referring to FIG. 6, a second mask 128 may be formed on the gate insulation layer 122 after removing the first mask 123 from the gate insulation layer 122. The second mask 128 may be formed using photoresist, organic material and/or oxide. The second mask 128 may expose a second portion of the epitaxial layer 105 on which a photo diode 130 is formed.

Third impurities and fourth impurities may be implanted into the second portion of the epitaxial layer 105 to form the photo diode 130. The photo diode 130 may have a lower layer including the third impurities and an upper layer including the fourth impurities. The lower layer of the photo diode 130 may have a sixth conductivity substantially different from the first conductivity of the epitaxial layer 105 while the upper portion of the photo diode 130 may have a seventh conductivity substantially the same as the first conductivity of the epitaxial layer 105. Thus, a depletion layer may be generated between the photo diode 130 and the epitaxial layer 105 to desirably operate the photo diode 130.

In example embodiments, the photo diode 130 may have a depth of about 5.4=from an upper face of the epitaxial layer 105. The photo diode 130 may absorb most red lights to improve sensitivity thereof. The depth of the photo diode 130 may be adjusted by implantation energy in an ion implantation process for forming the photo diode 130. The depletion layer may be formed on a portion of the epitaxial layer 105 beneath the photo diode 130. When the depletion layer has a relatively large area, electrical cross talk of the photo diode 130 may be reduced. Therefore, the epitaxial layer 150 may have a controlled impurity concentration considering the cross talk of the photo diode 130.

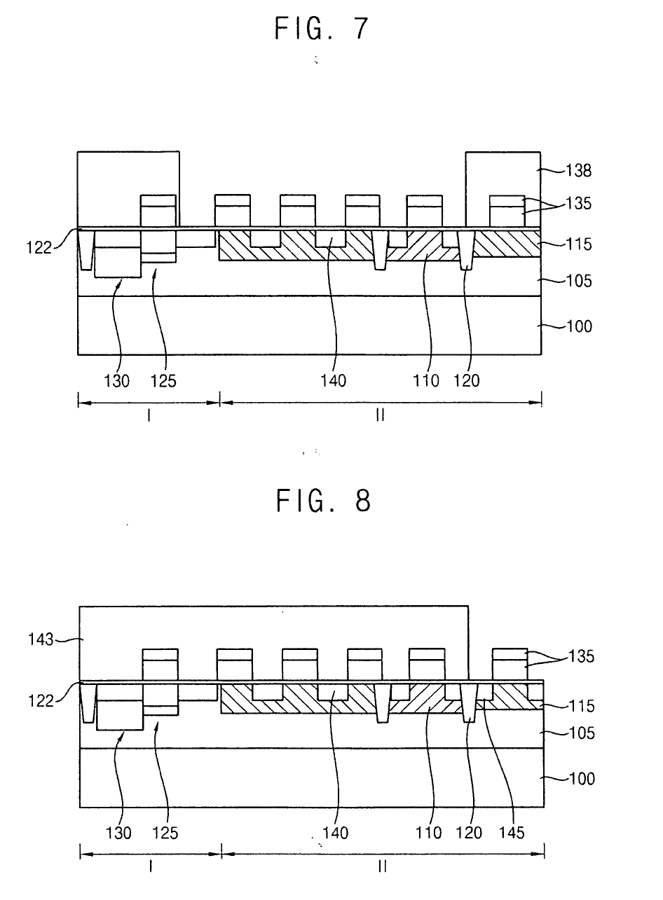

Referring to FIG. 7, gate structures 135 may be formed on the gate insulation layer 122. Each of the gate structures 135 may have a multi layer structure including a polysilicon layer, a metal layer and/or a metal compound layer. For example, the gate structures 135 may be formed using a doped polysilicon layer, a tungsten (W) layer, a titanium (Ti) layer, a tantalum (Ta) layer, an aluminum (Al) layer, a tungsten silicide (WSix) layer, a titanium silicide (TiSix) layer, a nickel silicide (NiSix) layer and/or a cobalt silicide (CoSix) layer. These may be used alone or in a combination thereof. Further, the gate structures 135 may be formed by a PECVD process, a CVD process, a sputtering process, an ALD process and/or an evaporation process.

In example embodiments, some of the gate structures 135 may be positioned on the first and the second wells 110 and 115, and another gate structure 135 may be provided on the gate channel 125 of the transfer transistor. A third mask 138 may be formed on the gate insulation layer 122. The third mask 138 may be formed using photoresist, organic material and/or nitride. The third mask 138 may expose portions of the gate insulation layer 122 and the gate structures 135 in the active pixel region. Thus, the gate structure 135 in the optical black pixel region may be covered with the third mask 138.

Using the third mask 138 as an implantation mask, fifth impurities may be doped into portions of the epitaxial layer 105 and the first well 110 to form first impurity regions 140 between adjacent gate structures 135. Each of the first impurity regions 140 may have an eighth conductivity and a relatively low impurity concentration. The eighth conductivity of the first impurity regions 140 may be substantially different from the first conductivity of the epitaxial layer 105.

Referring to FIG. 8, a fourth mask 143 may be formed on the gate insulation layer 122 to cover some of the gate structures 135 after removing the third mask 138. The fourth mask 143 may include photoresist, organic material and/or nitride. The fourth mask 143 may expose the gate structure 135 positioned over the second well 115 where a P type metal oxide semiconductor (PMOS) transistor is formed.

Sixth impurities may be implanted into portions of the second well 115 adjacent to the gate structure 135 using the fourth mask 143 as an implantation mask. Second impurity regions 145 may be formed on the portion of the second well 115 adjacent to the gate structure 135. Each of the second impurity regions 145 may have a ninth conductivity and a relatively low impurity concentration. The ninth conductivity of the second impurity regions 145 may be substantially the same as the first conductivity of the epitaxial layer 105. In example embodiments, the impurity concentration of the second impurity regions 145 may be substantially the same as or substantially similar to that of the first impurity regions 140. Alternatively, the impurity concentration of the first impurity regions 140 may be substantially different from that of the second impurity regions 145.

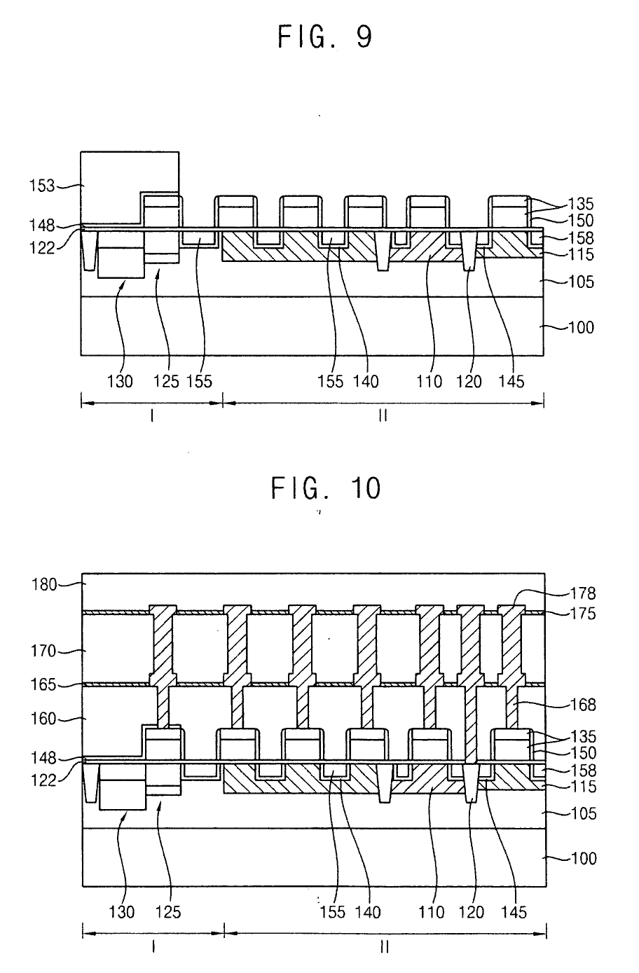

Referring to FIG. 9, after removing the fourth mask 143 from the gate insulation layer 122 and the gate structures 135, a spacer formation layer 148 may be formed on the gate insulation layer 122 and the gate structures 135. The spacer formation layer 148 may include nitride or oxynitride. For example, the spacer formation layer 148 may be formed using silicon nitride or silicon oxynitride. Further, the spacer formation layer 148 may be formed by a CVD process, a PECVD process and/or a low pressure chemical vapor deposition (LPCVD) process. The spacer formation layer 148 may have a thickness of about 500 Å.

A fifth mask 153 may be formed on a portion of the spacer formation layer 148 to cover the gate structure 135 adjacent to the photo diode 130. The fifth mask 153 may be formed using organic material and/or photoresist. After forming the fifth mask 153, portions of the spacer formation layer 148 positioned on the gate structures 135 on the first and the second wells 110 and 115 are exposed.

Using the fifth mask 153 as an etching mask, the exposed portions of the spacer formation layer 148 may be etched to provide spacers 150 on sidewalls of the gate structures 135 positioned on the first and the second wells 110 and 115. The spacers 150 may be obtained by an anisotropic etching process. The portion of the spacer formation layer 148 covered with the fifth mask 153 is not etched, so that the portion of the spacer formation layer 148 remains on the gate insulation layer 122 and the gate structure 135 adjacent to the photo diode 130.

Using the fifth mask 153 as an implantation mask, seventh and eighth impurities may be doped into the first and the second impurity regions 140 and 145, respectively. Thus, third impurity regions 155 may be formed on the first impurity regions 140 and fourth impurity regions 158 may be positioned on the second impurity regions 145. Each of the third and the fourth impurity regions 150 and 155 may have a relatively high impurity concentration substantially larger than those of the first and the second impurity regions 140 and 145. The third impurity regions 150 may have a tenth conductivity substantially the same as the first conductivity of the epitaxial layer 150 whereas the fourth impurity regions 158 may have an eleventh conductivity substantially different from the first conductivity of the epitaxial layer 105.

Referring to FIG. 10, a first insulation layer 160 may be formed on the gate insulation layer 122 to cover the gate structures 135, the spacers 150 and the remaining portion of the spacer formation layer 148 after removing the fifth mask from the remaining portion of the spacer formation layer 148. The first insulation layer 160 may be formed by a CVD process, a PECVD process, an LPCVD process and/or an HDP-CVD process. Additionally, the first insulation layer 160 may include SOG, USG FOX, BPSG, TEOS, TOSZ and/or HDP-CVD oxide. These may be used alone or in a mixture thereof.

In example embodiments, the first insulation layer 160 may be planarized by a planarization process to have a level upper face. For example, the first insulation layer 160 may be partially removed by a chemical mechanical polishing (CMP) process and/or an etch-back process. First contact holes (not illustrated) may be formed through the first insulation layer 160 by a photolithography process. Each of the first contact holes may expose each of the gate structures 135. The first contact holes may be formed by anisotropically etching first insulation layer 160.

A first conductive layer (not illustrated) may be formed on the first insulation layer 160 to fill the first contact holes, and the first conductive layer may be partially removed until the first insulation layer 160 is exposed. Therefore, lower wirings 168 may be formed in and on the first insulation layer 160. Each of the lower wirings 168 makes contact with each of the gate structures 135. The first conductive layer may include polysilicon, metal and/or metal compound. For example, the first conductive layer may be formed using doped polysilicon, tungsten, tungsten nitride (WNx), aluminum, aluminum nitride (AlNx), titanium, titanium nitride (TiNx), tantalum and/or tantalum nitride (TaNx). These may be used alone or in a mixture thereof. Further, the first conductive layer may be formed by a CVD process, an ALD process, a sputtering process, an evaporation process and/or a plating process.

A first etch stop layer 165 may be formed on the first insulation layer 160. The first etch stop layer 165 may include a material that has an etching selectivity relative to the first insulation layer 160 and the lower wirings 168. For example, the first etch stop layer 165 may be formed using nitride or oxynitride.

A second insulation layer 170 may be formed on the first etch stop 165 and the lower wirings 168. The second insulation layer 170 may be formed by a CVD process, a PECVD process, an LPCVD process and/or an HDP-CVD process. Further, the second insulation layer 170 may include SOG USG, FOX, BPS TEOS, TOSZ and/or HDP-CVD oxide. These may be used alone or in a mixture thereof. In example embodiments, the second insulation layer 170 may be planarized by a planarization process, e.g., a CMP process and/or an etch-back process, to have a level upper face.

Second contact holes (not illustrated) may be formed through the second insulation layer 170 by partially etching the second insulation layer 170 until the lower wirings 168 are exposed. The second contact holes may be formed by an anisotropic etching process.

A second conductive layer (not illustrated) may be formed on the lower wirings 168 to fill the second contact holes. The second conductive layer may be formed using polysilicon, metal and/or metal compound by a CVD process, an ALD process, a sputtering process, an evaporation process and/or a plating process. For example, the second conductive layer may include polysilicon doped with impurities, tungsten, tungsten nitride, aluminum, aluminum nitride, titanium, titanium nitride, tantalum and/or tantalum nitride. These may be used alone or in a mixture thereof. In example embodiments, the second conductive layer may include a conductive material substantially the same as or substantially similar to that of the first conductive layer. Alternatively, the second conductive layer may be formed using a conductive material substantially different from that of the first conductive layer.

The second conductive layer may be partially removed until the second insulation layer 170 is exposed, so that upper wirings 178 filling the second contact holes may be formed on the lower wirings 168. Each of the upper wirings 178 may be electrically connected to each of the lower wirings 168. In example embodiments, the lower wirings 168 and the upper wirings 178 may be included in a plurality of connections.

A second etch stop layer 175 may be formed on the second insulation layer 170. The second etch stop layer 175 may be formed using a material that has an etching selectivity relative to the second insulation layer 170 and the upper wirings 178. For example, the second etch stop layer 155 may include silicon nitride or silicon oxynitride.

A third insulation layer 180 may be formed on the second etch stop 175 and the upper wirings 178. The third insulation layer 180 may be formed using oxide by a CVD process, a PECVD process, an LPCVD process and/or an HDP-CVD process. For example, the third insulation layer 180 may include SOG, USG, FOX, BPSG, TEOS, TOSZ and/or HDP-CVD oxide. These may be used alone or in a mixture thereof. In example embodiments, the third insulation layer 180 may be planarized by a planarization process, e.g., a CMP process and/or an etch-back process, to ensure a level upper face thereof.

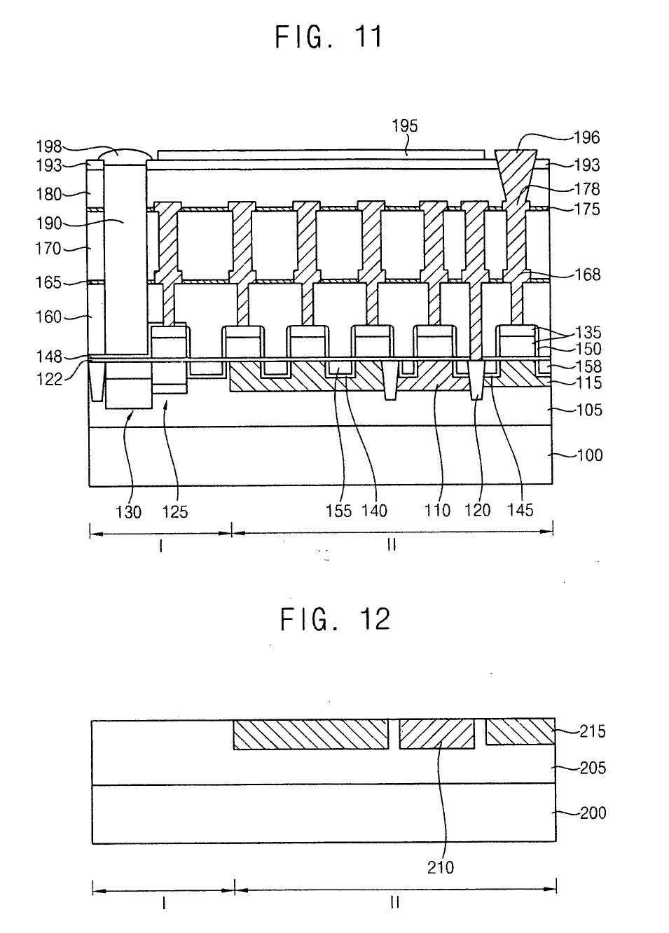

Referring to FIG. 11, an opening may be formed by partially etching the third insulation layer 180, the second etch stop layer 175, the second insulation layer 170, the first etch stop layer 165 and the first insulation layer 160. The opening may expose a portion of the remaining portion of the spacer formation layer 148 positioned over the photo diode 130. When the light is incident into the photo diode 130 through the opening, the loss of the light may be reduced because the light does not pass through all of the third insulation layer 180, the second etch stop layer 175, the second insulation layer 170, the first etch stop layer 165 and the first insulation layer 160.

A transparent layer 190 may be formed to fill the opening for transmitting the light into the photo diode 130 from an external source. The transparent layer 190 may be formed using transparent resin. The transparent layer 190 and the third insulation layer 180 may be planarized by a planarization process, such that the transparent layer 190 and the third insulation layer 180 may have flat upper faces.

A color filter layer (not illustrated) may be formed on the transparent layer 190. In example embodiments, three color filter layers may be formed on three transparent layers 190 when the image sensor includes a color filter array (CFA) of red, green and blue. Three photo diodes 130 corresponding to three color filter layers may be provided in the epitaxial layer 105.

In example embodiments, the substrate 100 having the color filter layer may be treated by hydrogen plasma to improve optical and electrical characteristics of the image sensor. For example, a hydrogen (H₂) gas and an argon (Ar) gas may be introduced into a chamber in which the substrate 100 having the color filter layer is loaded. The hydrogen plasma may be generated from the hydrogen gas, and the argon gas may serve as a carrier gas. In example embodiments, a flow rate ratio between the hydrogen gas and the argon gas may be in a range of about 4:1. For example, the hydrogen gas may be provided with a flow rate of about 200 sccm, and the argon gas may be introduced with a flow rate of about 50 sccm. An upper source voltage, a side source voltage and a bias voltage may be applied to the chamber to generate the hydrogen plasma from the hydrogen gas. For example, each of the upper and the side source voltages may be about 1,000 W and the bias voltage may be about 100 W. The hydrogen plasma treatment may be carried out at a temperature of about 300° C. to about 400° C. for about 60 seconds.

In the hydrogen plasma treatment, excited hydrogen ions may pass through the insulation layers 180, 170 and 160 and the etch stop layers 175 and 165, and may diffuse into portions of the substrate 100 adjacent to the photo diode 130. Due to the excited hydrogen ions, dangling bonds of silicon-oxygen (Si—O) and silicon-silicon (Si—Si) may be removed, so that dark current may not flow in the photo diode 130 and dark level difference between the active pixel region and the optical black pixel region may not occur. Accordingly, the image sensor may ensure improved electrical and optical characteristics.

Referring now to FIG. 11, a protection layer 193 may be formed on the third insulation layer 180. The protection layer 193 may be formed using organic material and/or oxide. A shielding member layer 195 may be formed on the protection layer 193 and a metal pad 196 may be formed on the upper wiring 178 through the third insulation layer 180. The shielding member 195 may include a material substantially the same as or substantially similar to that of the metal pad 196. When the shielding member 195 is formed on the protection layer 193, the color filter layer on the transparent layer 190 may be exposed.

A micro lens 198 may be formed on the exposed color filter layer. The desired color light of the lights passing through the color filter layer may be selected by the color filter layer, and the selected color light may progress through the transparent layer 190 to be accumulated into the photo diode 130.

According to example embodiments, the hydrogen plasma treatment may be performed before forming the shielding member 195, so that the excited hydrogen ions may be effectively diffused into the portion of the substrate 100 adjacent to the photo diode 130. Accordingly, the excited hydrogen ions may be widely diffused into the photo diode 130 and the substrate 100 near the photo diode 130 to effectively cure the dangling bonds of silicon-oxygen and silicon-silicon. As a result, the image sensor may have enhanced electrical and optical characteristics without the dark level difference and the dark current.

FIGS. 12 to 20 are cross sectional views illustrating a method of manufacturing an image sensor in accordance with example embodiments. The method illustrated in FIGS. 12 to 20 may manufacture an image sensor may having a back side illumination type where lights are irradiated into a back side of the image sensor. However, the method according to example embodiments may be employed in manufacturing normal CMOS image sensors or other image sensors, e.g., contact image sensors and/or solid state image sensors.

Referring to FIG. 12, a substrate 200 having a first region I and a second region II is provided. In example embodiments, the first region I and the second region II may correspond to an active pixel region and an optical black pixel region, respectively. Photo diodes may be formed in the first region I where lights pass and transfer transistors and CMOS transistors may be positioned in the second region II where the lights are not transmitted. The substrate 200 may include a semiconductor substrate, e.g., a silicon substrate, a germanium substrate and/or a silicon-germanium substrate. The substrate 200 may include impurities. For example, the substrate 200 may be doped with P type impurities or N type impurities in accordance with conductivity types of the transistors and the photo diodes.

An epitaxial layer 205 may be formed on the substrate 200. The epitaxial layer 205 may be obtained by an epitaxial growth process. The substrate 200 may serve as a seed for forming the epitaxial layer 205. The epitaxial layer 205 may have a first conductivity. For example, the first conductivity of the epitaxial layer 205 may be substantially the same as that of the substrate 200 when the epitaxial layer 205 is formed by the epitaxial growth process. Alternatively, the epitaxial layer 205 may have conductivity substantially different from that of the substrate 200 when different impurities are additionally doped into the epitaxial layer 205.

Because various structures or elements, e.g., the transistors or the photo diodes, may be formed on the epitaxial layer 205, the epitaxial layer 205 may have a relatively thick thickness. For example, the epitaxial layer 205 may have a thickness in a range of about 5 μm to about 15 μm measured from an upper face of the substrate 200. A first well 210 and a second well 215 may be formed in the epitaxial layer 205 by ion implantation processes and diffusion processes. The first well 210 may have a second conductivity and the second well 215 may have a third conductivity. For example, the first well 210 may have the second conductivity different from the first conductivity of the epitaxial layer 205, whereas the second well 215 may have the third conductivity substantially the same as the first conductivity of the epitaxial layer 205. The first and the second wells 210 and 215 may have various dimensions in accordance with required elements of the image sensor.

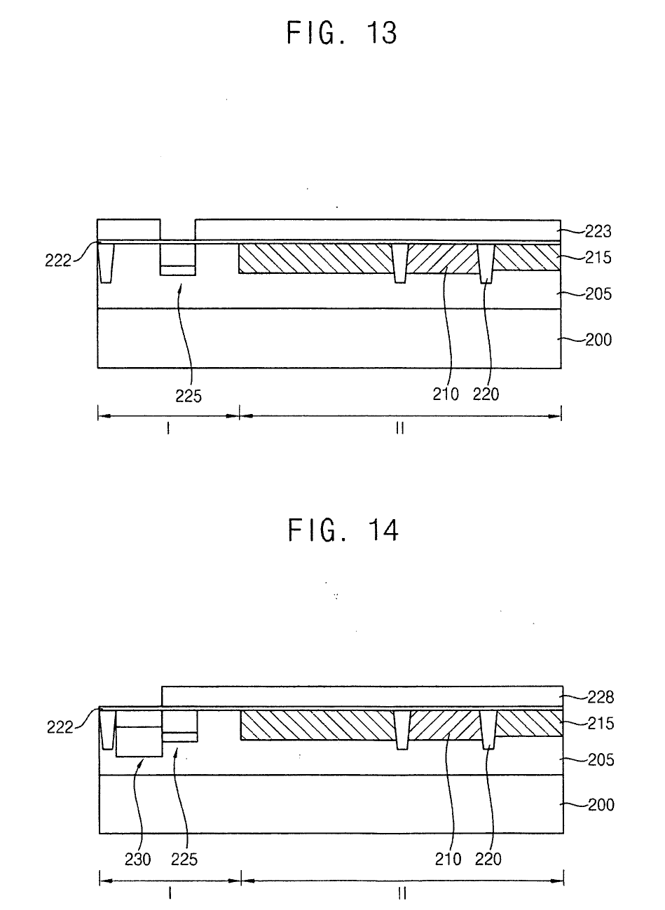

Referring to FIG. 13, an isolation layer 220 may be formed on a portion of the epitaxial layer 205 between the first well 210 and the second well 215. The isolation layer 220 may electrically separate the elements formed on the epitaxial layer 205. The isolation layer 220 may be formed using oxide by an STI process. For example, the isolation layer 220 may be formed using SOG. USG, FOX, PSG, BPSG, TEOS, TOSZ and/or HDP-CVD oxide.

In example embodiments, a plurality of isolation layers 220 may have different depths in accordance with the positions of the isolation layers 220. For example, each of the isolation layers 220 positioned in the second region II may have a thickness substantially different from that of the isolation layers 220 formed in the first region I. The isolation layers 220 in the first region I may a thickness of about 2.0 μm to electrically isolate the elements on the epitaxial layer 205 whereas the isolation layer 220 in the second region II may have a thickness substantially larger than that of the isolation layer 120 in the first region I. The photo diodes (not illustrated) may absorb red light, green light and blue light irradiated onto the epitaxial layer 205, so that the photo diodes may operate by accumulating the densities of the incident lights. For example, each photo diode may have a depth above about 2.0 μm because the red light may have the largest wavelength of about 0.4 μm to about 5.0 μm.

In example embodiments, the image sensor may have the back side illumination type, so that the isolation layer 220 may be adjacent to the substrate 200 in the second region II to prevent or reduce the red, the green and the blue lights irradiated onto the photo diode from being mixed one after another. Alternatively, an impurity region may be formed between the isolation layer 220 and the substrate 200 in the second region II where the photo diode is positioned, such that the lights may not be mixed when the lights are irradiated onto the photo diode through the substrate 200. When the isolation layer 220 and/or the impurity region is provided to enclose the photo diode, the light passing through the substrate 200 adjacent to the photo diode may not be refracted toward the photo diode, thereby preventing or reducing the lights from being mixed.

After the formation of the isolation layer 220, a gate insulation layer 222 may be formed on the epitaxial layer 205 on which the first and the second wells 210 and 215 are formed. The gate insulation layer 222 may cover the first and the second regions I and II. The gate insulation layer 222 may be formed using oxide and/or metal oxide by a CVD process, a thermal oxidation process, a PECVD process and/or an ALD process. For example, the gate insulation layer 222 may be formed using silicon oxide, hafnium oxide, aluminum oxide, zirconium oxide and/or tantalum oxide. These may be used alone or in a mixture thereof.

A first mask 223 may be formed on the gate insulation layer 222. The first mask 223 may be formed using photoresist, organic material and/or nitride. The first mask 223 may expose a first portion of the epitaxial layer 205 where the transfer transistor will be formed.

First and second impurities may be implanted into the first portion of the epitaxial layer 205 using first mask 223 as an implantation mask, so that a gate channel 225 of the transfer transistor may be formed on the first portion of the epitaxial layer 205. The first impurities and the second impurities may have a fourth conductivity and a fifth conductivity, respectively. The fourth conductivity of the first impurities may be substantially the same as the first conductivity of the epitaxial layer 205 whereas the fifth conductivity of the second impurities may be substantially different from the first conductivity of the epitaxial layer 205. Alternatively, the fourth conductivity of the first impurities may be substantially different from the first conductivity and the fifth conductivity of the second impurities may be substantially the same as the first conductivity. That is, the conductivities of the first and the second impurities may vary in accordance with the conductivity of the gate channel 225.

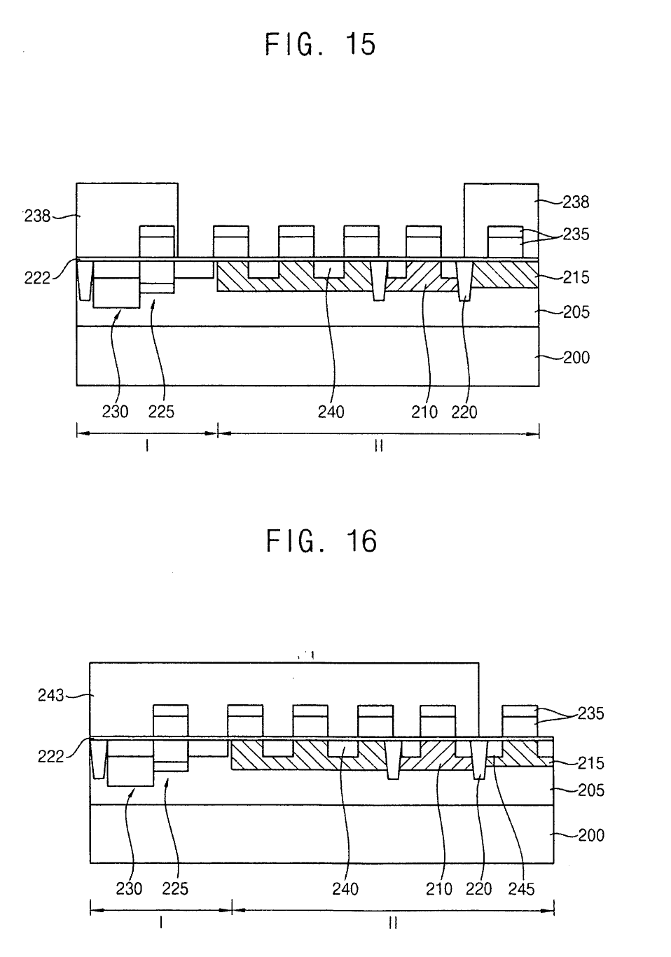

Referring to FIG. 14, a second mask 228 may be formed on the gate insulation layer 222 after removing the first mask 223. The second mask 228 may be formed using photoresist, organic material and/or oxide. The second mask 228 may expose a second portion of the epitaxial layer 205 on which a photo diode 230 will be formed.

Third impurities and fourth impurities may be doped into the second portion of the epitaxial layer 205, such that the photo diode 230 may be formed on the second portion of the epitaxial layer 205. The photo diode 230 may have a lower layer including the third impurities and an upper layer having the fourth impurities. The lower layer of the photo diode 230 may have a sixth conductivity substantially different from the first conductivity of the epitaxial layer 205 whereas the upper portion of the photo diode 230 may have a seventh conductivity substantially the same as the first conductivity of the epitaxial layer 205. Therefore, a depletion layer may be generated between the photo diode 230 and the epitaxial layer 205 to operate the photo diode 230.

The photo diode 230 may have a depth of about 5.0 μm measured from an upper face of the epitaxial layer 205, so that the photo diode 230 may absorb most of the red lights to improve sensitivity thereof. The depth of the photo diode 230 may be adjusted by implantation energy in an ion implantation process for forming the photo diode 230. The depletion layer may be formed on a portion of the epitaxial layer 205 beneath the photo diode 230. When the depletion layer has a relatively large area, electrical cross talk of the photo diode 230 may be reduced. Therefore, the epitaxial layer 250 may have a controlled impurity concentration considering the cross talk of the photo diode 230.

Referring to FIG. 15, gate structures 235 may be formed on the gate insulation layer 222 in the first region I. Each of the gate structures 235 may have a multi layer structure including a polysilicon layer, a metal layer and/or a metal compound layer. For example, the gate structures 235 may include a doped polysilicon layer, a tungsten layer, a titanium layer, a tantalum layer, an aluminum layer, a tungsten silicide layer, a titanium silicide layer, a nickel silicide layer and/or a cobalt silicide layer. The gate structures 235 may be formed by a PECVD process, a CVD process, a sputtering process, an ALD process and/or an evaporation process. In example embodiments, some gate structures 235 may be positioned on the first and the second wells 210 and 215, and another gate structure 235 may be provided on the gate channel 225 of the transfer transistor.

A third mask 238 may be formed on the gate insulation layer 222. The third mask 238 may be formed using photoresist, organic material and/or nitride. The third mask 238 may expose portions of the gate insulation layer 222 and the gate structures 235 in the first region I, so that the gate structure 235 on the gate channel 225 may be covered with the third mask 238.

Fifth impurities may be doped into portions of the epitaxial layer 205 and the first well 210 using the third mask 238 as an implantation mask to form first impurity regions 240 between adjacent gate structures 235. Each of the first impurity regions 240 may have an eighth conductivity and a relatively low impurity concentration. The eighth conductivity of the first impurity regions 240 may be substantially different from the first conductivity of the epitaxial layer 205.

Referring to FIG. 16, a fourth mask 243 may be formed on the gate insulation layer 222 to cover some gate structures 235 after removing the third mask 238 form the gate insulation layer 222. The fourth mask 243 may include photoresist, organic material and/or nitride. The fourth mask 243 may expose the gate structure 235 positioned over the second well 215 where the transistors are formed.

Sixth impurities may be implanted into portions of the second well 215 adjacent to the gate structure 235 using the fourth mask 243 as an implantation mask. Thus, second impurity regions 245 may be formed on the portions of second well 215 adjacent to the gate structure 235. Each second impurity regions 245 may have a ninth conductivity and a relatively low impurity concentration. The ninth conductivity of the second impurity regions 245 may be substantially the same as the first conductivity of the epitaxial layer 205. In example embodiments, the impurity concentration of each second impurity region 245 may be substantially the same as or substantially similar to that of each first impurity region 240. Alternatively, the impurity concentrations of the first impurity regions 240 may be substantially different from those of the second impurity regions 245.

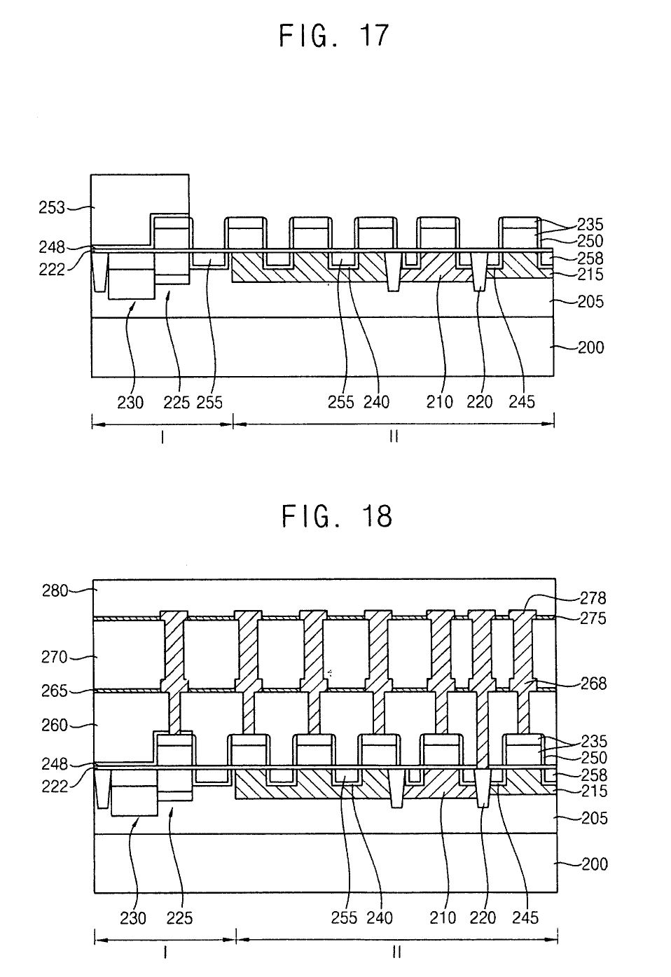

Referring to FIG. 17, after removing the fourth mask 243 from the gate insulation layer 222 and the gate structures 235, a spacer formation layer 248 may be formed on the gate insulation layer 222 and the gate structures 235. The spacer formation layer 248 may include nitride or oxynitride. For example, the spacer formation layer 248 may be formed using silicon nitride or silicon oxynitride. Further, the spacer formation layer 248 may be formed by a CVD process, a PECVD process and/or an LPCVD process. The spacer formation layer 248 may have a thickness of about 500 Å.

A fifth mask 253 may be formed on a portion of the spacer formation layer to cover the gate structure 235 adjacent to the photo diode 230. The fifth mask 253 may include organic material and/or photoresist. After forming the fifth mask 253, portions of the spacer formation layer 248 positioned on the gate structures 235 on the first and the second wells 210 and 215 are exposed.

The exposed portions of the spacer formation layer 248 may be etched using the fifth mask 253 as an etching mask to form spacers 250 on sidewalls of the gate structures 235 positioned on the first and the second wells 210 and 215. The spacers 250 may be obtained by an anisotropic etching process. Because a portion of the spacer formation layer 248 covered with the fifth mask 253 is not etched, the portion of the spacer formation layer 248 remains on the gate insulation layer 222 and the gate structure 235 adjacent to the photo diode 230.

Seventh and eighth impurities may be doped into the first and the second impurity regions 240 and 245, respectively using the fifth mask 253 as an implantation mask. Third impurity regions 255 and fourth impurity regions 258 may be formed on the first impurity regions 240 and the second impurity regions 245, respectively. Each of the third and the fourth impurity regions 250 and 255 may have a relatively high impurity concentration substantially larger than those of the first and the second impurity regions 240 and 245. The third impurity regions 250 may have a tenth conductivity substantially the same as the first conductivity of the epitaxial layer 250 whereas the fourth impurity regions 258 may have an eleventh conductivity substantially different from the first conductivity of the epitaxial layer 205.

Referring to FIG. 18, a first insulation layer 260 may be formed on the gate insulation layer 222 to cover the gate structures 235, the spacers 250 and the remaining portion of the spacer formation layer 248 after removing the fifth mask 253 from the remaining portion of the spacer formation layer 248. The first insulation layer 260 may be formed using oxide by a CVD process, a PECVD process, an LPCVD process and/or an HDP-CVD process. For example, the first insulation layer 260 may be formed using SOG, USG, FOX, BPSG, PE-TEOS, TEOS, TOSZ and/or HDP-CVD oxide. These may be used alone or in a mixture thereof. In example embodiments, the first insulation layer 260 may be planarized by a planarization process to have a level upper face. The first insulation layer 260 may be partially removed by a CMP process and/or an etch-back process.

First contact holes (not illustrated) may be formed through the first insulation layer 260 by partially etching the first insulation layer 260. Each of the first contact holes may expose each of the gate structures 235. The first contact holes may be formed by anisotropically etching first insulation layer 260.

A first conductive layer (not illustrated) may be formed on the first insulation layer 260 to fill the first contact holes, and the first conductive layer may be removed until the first insulation layer 260 is exposed. Thus, lower wirings 268 may be formed in and on the first insulation layer 260. Each lower wiring 268 may make contact with each gate structure 235. The lower wirings 268 may include polysilicon, metal and/or metal compound obtained by a CVD process, an ALD process, a sputtering process, an evaporation process and/or a plating process. For example, each of the lower wirings 268 may include doped polysilicon, tungsten, tungsten nitride, aluminum, aluminum nitride, titanium, titanium nitride, tantalum and/or tantalum nitride. These may be used alone or in a mixture thereof.

A first etch stop layer 265 may be formed on the first insulation layer 260. The first etch stop layer 265 may include a material that has an etching selectivity relative to the first insulation layer 260 and the lower wirings 268. For example, the first etch stop layer 265 may be formed using nitride or oxynitride.

A second insulation layer 270 may be formed on the first etch stop 265 and the lower wirings 268. The second insulation layer 270 may be formed using oxide by a CVD process, a PECVD process, an LPCVD process and/or an HDP-CVD process. For example, the second insulation layer 270 may be formed using SOG, USG, FOX, BPSG, TEOS, TOSZ and/or HDP-CVD oxide. These may be used alone or in a mixture thereof. The second insulation layer 270 may be planarized by a planarization process, e.g., a CMP process and/or an etch-back process, to have a level upper face thereof. Second contact holes (not illustrated) may be formed through the second insulation layer 270 by partially etching the second insulation layer 270 until the lower wirings 268 are exposed. The second contact holes may be formed by an anisotropic etching process.

A second conductive layer (not illustrated) may be formed on the lower wirings 268 to fill the second contact holes. The second conductive layer may be formed using polysilicon, metal and/or metal compound by a CVD process, an ALD process, a sputtering process, an evaporation process and/or a plating process. For example, the second conductive layer may include polysilicon doped with impurities, tungsten, tungsten nitride, aluminum, aluminum nitride, titanium, titanium nitride, tantalum and/or tantalum nitride. These may be used alone or in a mixture thereof. The second conductive layer may include a conductive material substantially the same as or substantially similar to that of the first conductive layer. Alternatively, the second conductive layer may be formed using a conductive material substantially different from that of the first conductive layer.

The second conductive layer may be partially removed until the second insulation layer 270 is exposed to form upper wirings 278 filling the second contact holes on the lower wirings 268. Each of the upper wirings 278 may be electrically connected to each of the lower wirings 268. A second etch stop layer 275 may be formed on the second insulation layer 270. The second etch stop layer 275 may be formed using a material that has an etching selectivity relative to the second insulation layer 270 and the upper wirings 278. For example, the second etch stop layer 275 may include silicon nitride or silicon oxynitride.

A third insulation layer 280 may be formed on the second etch stop 275 and the upper wirings 278. The third insulation layer 280 may be formed using oxide by a CVD process, a PECVD process, an LPCVD process and/or an HDP-CVD process. For example, the third insulation layer 280 may include SOG, USG, FOX, BPSG, TEOS, TOSZ and/or HDP-CVD oxide. These may be used alone or in a mixture thereof. The third insulation layer 280 may be planarized by a planarization process, e.g., a CMP process and/or an etch-back process, to ensure a level upper face thereof.

Referring to FIG. 19, after an additional substrate 285 is provided on the third insulation layer 280, the substrate 200 having the resultant structures may be turned upside down. The substrate 200 may be removed until the epitaxial layer 205 is exposed. The substrate 200 may be removed by a thinning process. In example embodiments, the additional substrate 285 may include a handling wafer. The additional substrate 285 may also include a first region I and a second region II substantially corresponding to those of the substrate 200. For example, the first and the second regions I and II of the additional substrate 285 may correspond to the active pixel and the optical black pixel regions of the substrate 200 or the epitaxial layer 205.

A hydrogen plasma treatment may be performed about the epitaxial layer 205 having the photo diode 230 thereon to cure the dangling bonds of silicon-oxygen and/or adjacent silicons. The plasma treatment process may be carried out in a high density plasma chamber. In example embodiments, a hydrogen gas and an inactive gas, e.g., an argon gas, may be introduced into the chamber in which the resultant structures are loaded. The hydrogen plasma may be generated from the hydrogen gas, and the argon gas may serve as a carrier gas. A flow rate ratio between the hydrogen gas and the argon gas may be in a range of about 4:1. For example, the hydrogen gas may be provided with a flow rate of about 200 sccm, and the argon gas may be introduced with a flow rate of about 50 sccm. An upper source voltage, a side source voltage and a bias voltage may be applied to the chamber to generate the hydrogen plasma from the hydrogen gas. Each of the upper and the side source voltages may be about 1,000 W and the bias voltage may be about 100 W. The hydrogen plasma treatment may be carried out at a temperature of about 300° C. to about 400° C. for about 60 seconds.

In the hydrogen plasma treatment, excited hydrogen ions may be implanted into the epitaxial layer 205 and may diffuse into portions of the epitaxial layer 205 adjacent to the photo diode 230. Owing to the excited hydrogen ions, dangling bonds of silicon-oxygen and/or silicon-silicon in the epitaxial layer may be removed, such that dark current may not flow in the photo diode 230 and dark level difference between the first region I and the second may not occur. Therefore, the image sensor may ensure improved electrical and optical characteristics.

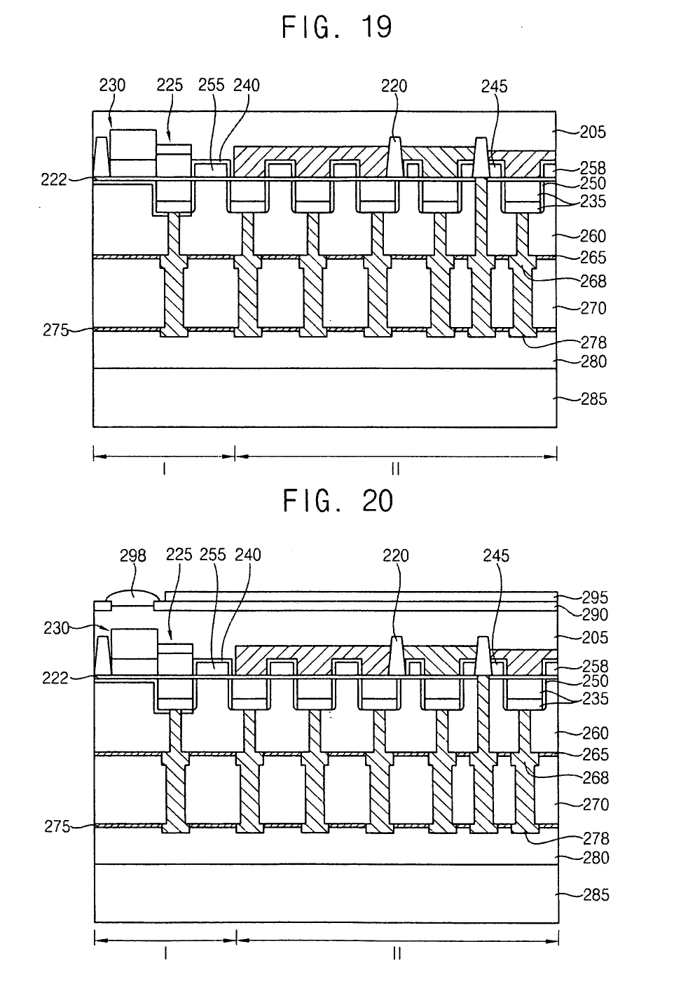

Referring to FIG. 20, a protection layer 290 may be formed on the epitaxial layer 205. The protection layer 290 may be formed using organic material and/or oxide. The protection layer 290 may expose a portion of the epitaxial layer 205 under which the photo diode 230 is positioned.

A color filter layer (not illustrated) may be formed on the exposed portion of the epitaxial layer 205. In example embodiments, three color filter layers may be formed on three exposed portions of the epitaxial layer 205 when the image sensor may include a CFA of red, green and blue. Further, three photo diodes 230 corresponding to three color filter layers may be provided in the epitaxial layer 205.

A micro lens 298 may be formed on the color filter layer, and a shielding member 295 may be formed on the protection layer 290. The shielding member 295 may include a metal and/or a metal compound. For example, the shielding member 295 may be formed using tungsten, tungsten nitride, titanium, titanium nitride, aluminum, aluminum nitride, titanium aluminum nitride, tantalum and/or tantalum nitride. These may be used alone or in a mixture thereof. Further, the shielding member 295 may be formed by a sputtering process, a CVD process, an ALD process, a PECVD process and/or an evaporation process. In example embodiments, the desired color lights passing through the micro lens 298 may be selected by the color filter layer, and the selected color lights may progress through the epitaxial layer 205 to be accumulated into the photo diode 230.

According to example embodiments, the hydrogen plasma treatment may be carried out before forming the shielding member 295. Thus, the excited hydrogen ions may be effectively diffused into the portion of the epitaxial layer 205 on the photo diode 230. The excited hydrogen ions may be widely diffused into the photo diode 330 and the epitaxial layer 205 near the photo diode 230 to effectively cure the dangling bonds of silicon-oxygen and silicon-silicon. Therefore, the image sensor may have enhanced electrical and optical characteristics without the dark level difference and the dark current.

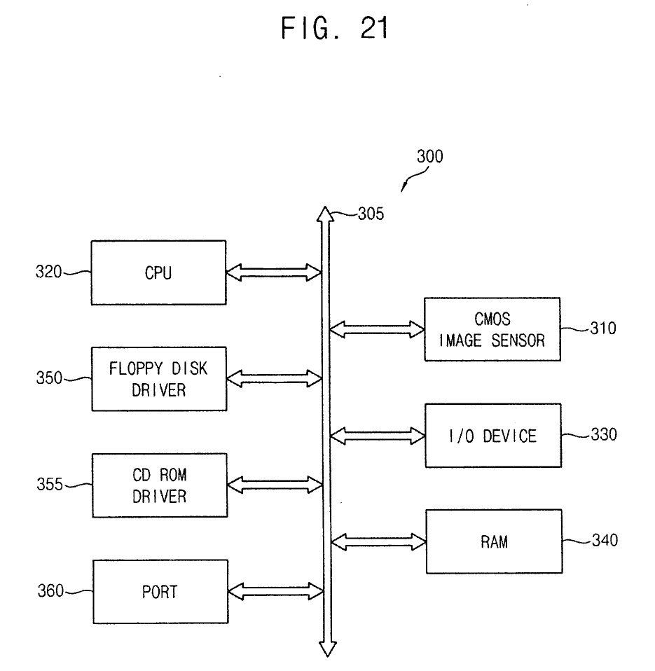

FIG. 21 is a block diagram illustrating an electronic system including a CMOS image sensor in accordance with example embodiments. An electronic system 300 illustrated in FIG. 21 may process the images produced from a CMOS image sensor 310 having a shielding member formed after a hydrogen plasma treatment. For example, the electronic system 300 may include a computer system, a digital camera system, a scanner and/or other image processing system.

Referring to FIG. 21, the electronic system 300 may include the CMOS image sensor 310, a central processing unit (CPU) 320, an input/output (I/O) element 330, a random access memory (RAM) 340, a floppy disk driver 350, a compact disc read only memory (CD ROM) driver 355, and a port 360. The CPU 320 may communicate with the I/O element 330 through a bus 305. The RAM 340, the floppy disk driver 350, the CD ROM driver 355 and/or the port 360 may transfer electrical data through the bus 305, so that the electronic system 300 may process the image data obtained by the CMOS image sensor 310.

In example embodiments, the port 360 may be coupled to a video card, a sound card, a memory card and/or a universal serial bus (USB). Alternatively, the port 360 may be electrically connected to other electronic systems for transferring the data. The CMOS image sensor 310 may be integrated with the CPU 320, a digital signal processing (DSP) device and/or a micro processer. Alternatively, the CMOS image sensor 310 may be integrated with a memory device, e.g., a flash memory device.

When the CMOS image sensor 310 may include the shielding member after performing the hydrogen plasma treatment, the CMOS image sensor 310 may improve the quality of the image generated thereof because defects, e.g., dangling bonds, are cured by the hydrogen plasma treatment. Therefore, the electronic system 300 may also ensure enhanced optical and electrical characteristics.

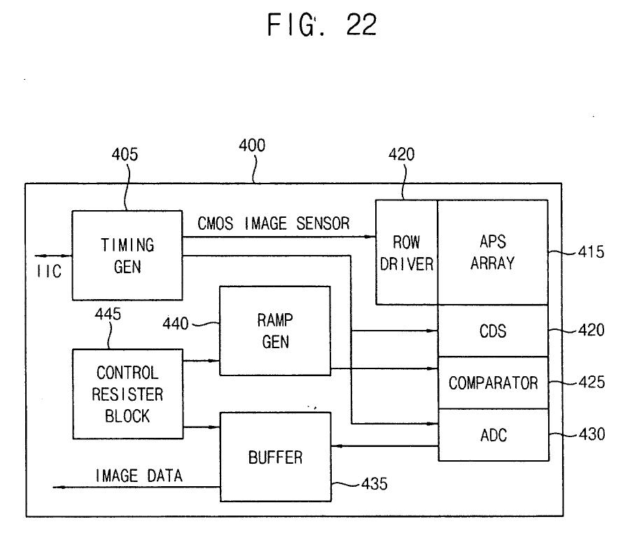

FIG. 22 is a block diagram illustrating a CMOS image sensor including a shielding member in accordance with example embodiments. In FIG. 22, a CMOS image sensor 400 may be employed as a separated chip for other electronic system. Referring to FIG. 22, the CMOS image sensor 400 may include a timing generator 405, an APS array 415, a correlated double sampling (CDS) device 420, a comparator 425, an analogue-digital converter (ADC) 430, a buffer 435, a ramp generator 440, and a control resistor block 445.

The images of objects and data captured by the APS array 415 may be converted as charges through an electron conversion, and the charges may be converted into predetermined or given signals through a voltage conversion. The CDS device 420 may remove noises from the predetermined or given signals and may select required signals. The comparator 420 may identify the selected signals based on reference signals, and the identified signals may be converted into digital signals of the image in the ADC 430. The digital signals of the image may be displayed by the CMOS image sensor 400 through the buffer 435 and the control resistor block 445.

According to example embodiments, the CMOS image sensor 400 may display the image of the object with a higher quality because the CMOS image sensor may include a shielding member after performing a hydrogen plasma treatment.

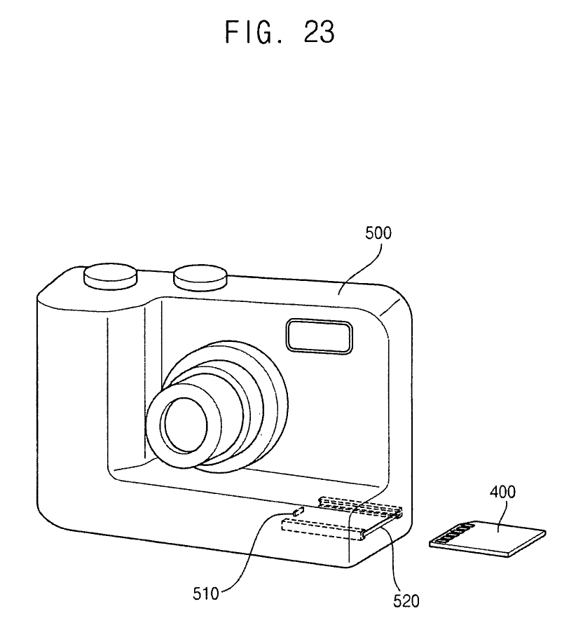

FIG. 23 is a block diagram illustrating another electronic system including a CMOS image sensor in accordance with example embodiments. As illustrated in FIG. 23, a CMOS image sensor 400 described with reference to FIG. 22 may be employed in a digital camera system 500.

Referring to FIG. 23, the digital camera system 500 may include a digital signal processor (DSP) 510 having a camera controller (not illustrated) and an image signal processor (not illustrated). The CMOS image sensor 400 may be inserted into a receiving member 520 of the digital camera system 500, so that the CMOS image sensor 400 may electrically make contact with the DSP 510 to store an image of an object obtained by the digital camera system 500 or to display an image of an object stored in the CMOS image sensor 400.

As described above, the CMOS image sensor 400 may include a shielding member after performing a hydrogen plasma treatment, so that the digital camera system 500 may ensure a higher quality image. For example, the digital camera system 500 may provide the image of the object without the dark level difference of the image and/or the white spot of the image.

According to example embodiments, dangling bonds of silicon-oxygen and/or silicon-silicon may be effectively removed from a substrate or an epitaxial layer on which a photo diode of an image sensor is positioned. Thus, the image sensor may improve the quality of the image with enhanced electrical and optical characteristics while preventing or reducing the dark level difference of the image and/or the dark current in the photo diode. When the image sensor is coupled to a memory device, e.g., a flash memory device, the image of the object may be more easily stored or displayed with the desired higher quality. Further, the image sensor may be sufficiently employed in various electronic systems, for example, mobile phones, digital cameras, video games, video conference systems and/or telemedicine systems.

The foregoing is illustrative of example embodiments, and is not to be construed as limiting thereof. Although a few example embodiments have been described, those skilled in the art will readily appreciate that many modifications are possible in example embodiments without materially departing from the novel teachings and advantages of example embodiments. Accordingly, all such modifications are intended to be included within the scope of the inventive concept as defined in the claims. In the claims, means-plus-function clauses are intended to cover the structures described herein as performing the recited function and not only structural equivalents but also equivalent structures. Therefore, it is to be understood that the foregoing is illustrative of the inventive concept and is not to be construed as limited to the specific example embodiments disclosed, and that modifications to the disclosed example embodiments, as well as other example embodiments, are intended to be included within the scope and defined by the appended claims.

1-10. (canceled)

11. A method of manufacturing an image sensor, comprising
forming an epitaxial layer on a substrate having a first region and a second region;
forming a photo diode on a first portion of the epitaxial layer in the first region of the substrate;
forming at least one transfer transistor on the epitaxial layer adjacent to the photo diode;
forming a plurality of transistors on a second portion of the epitaxial layer in the second region of the substrate;
forming an insulation layer to cover the photo diode, the at least one transfer transistor and the plurality of transistors on the epitaxial layer;
forming a plurality of connections through the insulation layer to electrically connect with the at least one transfer transistor and the plurality of transistors in the second region of the substrate; and
forming a shielding member exposing the photo diode.

12. The method of claim 11, further comprising:
forming a first well and a second well on the second portion of the epitaxial layer before forming the photo diode.

13. The method of claim 11, further comprising:
treating the epitaxial layer and the substrate with a hydrogen plasma before forming the shielding member to remove dangling bonds of silicon-oxygen and/or silicon-silicon in the epitaxial layer and the substrate.

14. The method of claim 13, wherein treating the epitaxial layer and the substrate is performed using a hydrogen (H₂) gas and an argon (Ar) gas at a temperature of about 300° C. to about 400° C.

15. The method of claim 11, further comprising:
forming a transparent layer on the photo diode through the insulation layer in the first region of the substrate; and
forming a protection layer on the insulation layer to cover the plurality of connections.

16. The method of claim 15, further comprising:
forming a color filter layer on the transparent layer; and
forming a micro lens on the color filter layer.

17. The method of claim 11, further comprising:
forming a metal pad through the insulation layer to electrically connect with the plurality of connections.

18. The method of claim 17, wherein the shielding member and the metal pad are formed simultaneously.

19. The method of claim 11, further comprising:
forming an additional substrate on the insulation layer before forming the shielding layer; and
removing the substrate from the epitaxial layer.

20. The method of claim 19, further comprising:
forming a protection layer between the epitaxial layer and the shielding member; and
treating the epitaxial layer with a hydrogen plasma before forming the shielding member.
